(19) United States
(12) Patent Application Publication
(10) Pub. No.: US 2011/0169669 A1
(43) Pub. Date: Jul. 14, 2011

(54) KEYBOARD WITH TRANSPARENT KEY PADS

(76) Inventor: Cyrille de Brebisson, Boise, ID (US)

(21) Appl. No.: 13/063,619

(22) PCT Filed: Sep. 12, 2008
(86) PCT No.: PCT/US08/76130

§ 371 Date: Mar. 11, 2011

(51) Int. Cl. H03M 11/00

(52) U.S. Cl. 341/22

(57) ABSTRACT

Systems, methods, and other embodiments associated with keyboards are described. One example keyboard includes a printed circuit board to control input responses associated to key pads being touched. The keyboard further includes a plurality of transparent key pads flexibly coupled to the printed circuit board. A layer of key labels is disposed between the printed circuit board and the plurality of transparent key pads. The layer of key labels includes symbols visible through the plurality of transparent key pads to identify a corresponding transparent key pad. The layer of key labels is removable and replaceable with a different layer of key labels.

### BACKGROUND

Keyboards are widely used for interfacing with electronic devices such as computers, calculators, and other consumer products. Keyboards have key pads/buttons that are pressed or touched to enter an input or perform some action that is associated with the pressed key pad. Each key pad will have a symbol directly printed on or permanently attached to the key pad, which represents what the key pad is programmed to do. Because consumer products are mass produced for large commercial markets that use English text and symbols, it is costly to manufacture and assemble custom key pads for different regions of the world that use non-English alphabets or other languages. In these regions, it has been more difficult for non-English users to learn and operate consumer products that have English-based keypads.

### BRIEF DESCRIPTION OF THE DRAWINGS

The accompanying drawings, which are incorporated in and constitute a part of the specification, illustrate various example systems, methods, and other example embodiments of various aspects of the invention. It will be appreciated that the illustrated element boundaries (e.g., boxes, groups of boxes, or other shapes) in the figures represent one example of the boundaries. One of ordinary skill in the art will appreciate that in some examples one element may be designed as multiple elements or that multiple elements may be designed as one element. In some examples, an element shown as an internal component of another element may be implemented as an external component and vice versa. Furthermore, elements may not be drawn to scale.

FIG. 1 illustrates an example partial side view of one embodiment of a keyboard.

FIG. 2 illustrates an example partial cross section view of one embodiment of layers forming a keyboard.

FIG. 3 illustrates an example top view of one embodiment of an electronic device with key pads.

FIG. 4 illustrates an example exploded view of another embodiment of an electronic device showing layers of the keyboard.

FIG. 5 illustrates one embodiment of a method associated with forming a transparent keyboard.

### DETAILED DESCRIPTION

Described herein are example systems, methods and other embodiments associated with keyboards and electronic devices with keyboards. In one embodiment, a keyboard includes transparent key pads mounted over a printed circuit board. A separate label sheet is disposed between the transparent key pads and the printed circuit board to provide desired labeling for each key pad. The labeling identifies a key pad, an input response, and/or action associated with the corresponding transparent key pad when the key pad is touched. In one embodiment, the label sheet may be a sheet of paper, plastic, or other suitable material with symbols that identify one or more key pads. The sheet is aligned under the transparent key pads so that a corresponding symbol is underneath and visible through a transparent key pad that the symbol identifies.

The keyboard is designed so that the label sheet may be easily removed and replaced with a different label sheet (e.g. a sheet with symbols/text in a different language). This allows the keyboard to be easily customized for individual countries and markets rather than having to manufacture and/or assemble a customized set of key pads for each desired country or market. Changing the sheet will not alter the functionality of the device or the key pads. The device still performs the same function when the keypad is pressed. Because the label sheet can be printed in any desired language and Inserted into the keyboard, the user interface and keyboard of an electronic device can be customized and can provide an improved user experience.

References to “one embodiment”, “an embodiment”, “one example”, “an example”, and so on, indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrase “in one embodiment” does not necessarily refer to the same embodiment, though it may.

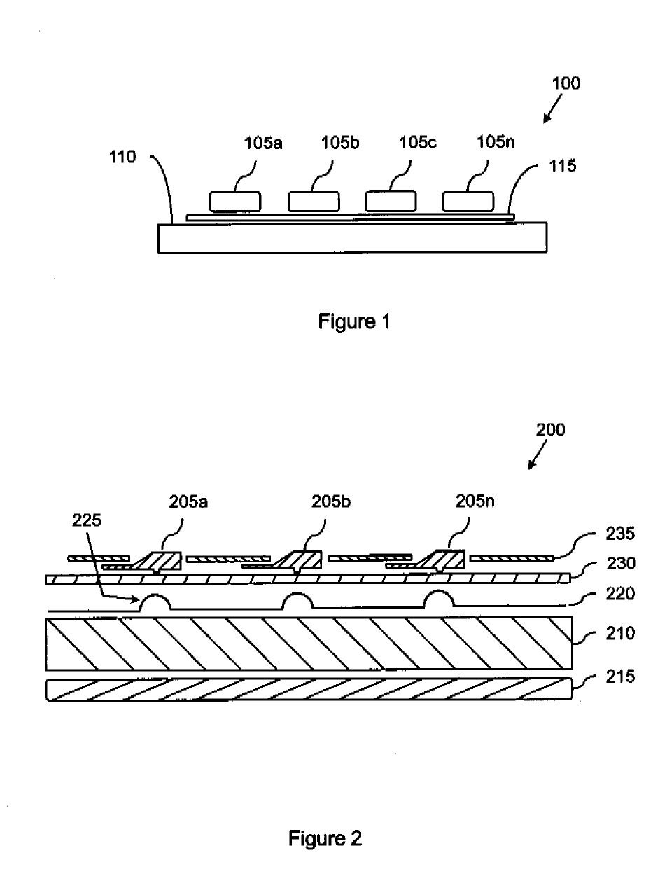

With reference to FIG. 1, one embodiment of a keyboard 100 is illustrated in a partial side-view. The keyboard 100 is configured with a plurality of transparent key pads 105a-n, although any number and combination of key pads can be used. The keyboard 100 includes a printed circuit board (PCB) 110 to control input responses associated to the key pads 105a-n being touched or pressed. In one embodiment, the transparent key pads 105a-n are flexibly coupled to the printed circuit board 110 so that an electrical connection is made and/or a signal is generated when a particular keypad is pressed.

A layer of key labels 115 is disposed between the printed circuit board 110 and the transparent key pads 105a-n. The layer of key labels 115 includes symbols that are visible through the transparent key pads 105a-n to identify an associated key pad when aligned. For example, a symbol identifies an input response associated with a corresponding transparent key pad 105a-n when a key pad is touched. Key pads can be identified with numerals (e.g. 1, 2, 3 . . . ), characters (e.g. A, B, +, −, < . . . ), functions (e.g. enter, delete, multiply, sine, . . . ), and so on. The input response identifies what happens when a key pad is pressed (e.g. input the character “A”, perform multiply operation, etc).

The layer of key labels 115 is removable so that it may be replaced with a different layer of key labels with different labels. For example, replacing English-based key labels with a sheet of non English-based labels allows the Identification of the key pads to be easily converted and customized to a selected language and/or consumer market. If an electronic device Is to be sold in China, then a Chinese character-based sheet of key labels 115 can be inserted into the keyboard to identify the key pads 105a-n. Similarly, Arabic countries use different symbols, text and numerals than English-based alphabets. Thus an Arabic layer of key labels 115 would make the keyboard 100 and its electronic device easier to use for Arabic users.

To allow the layer of key labels 115 to be removed, the keyboard 100 can be opened or partially opened to allow the removal of existing key labels and insertion of a different layer of key labels 115. In one embodiment, the bottom cover and the upper cover are configured to be interlocked together by snapping the upper cover to the bottom cover. These two components may be unsnapped to allow the layer of key labels 115 to be changed. In another embodiment, the bottom cover and the upper cover are fastened together with one or more screws. In another embodiment, the keyboard 100 can include a slot or custom door though a housing/case configured to allow the layer of key labels 115 to be removed and inserted by sliding the layer in and out of the slot. With a slot, the key label sheet 230 can be removed without the transparent key pads 105a-n or other keyboard components being removed.

It is much more economical to change the symbols for the transparent key pads 105a-n with the layer of key labels 115 rather than changing each of the transparent key pads 105a-n. In some embodiments, the layer of key labels 115 may be changed by the user of the keyboard 100, the local retailer, or the manufacturer of the keyboard 100.

In some embodiments, the transparent key pads 105a-n are configured to visually enhance the symbols on the layer of key labels 115. In one embodiment, the transparent key pads 105a-n are shaped as lenses or include lenses that allow the symbol(s) on the layer of key labels 115 under the key pad to be better seen. For example, the lenses may magnify the symbol.

Other embodiments may further include a transparent sheet disposed between the upper cover and the layer of key labels 115. The transparent sheet may be rubber and may help to keep the keyboard 100 clean and/or improve the tactile feel of the transparent key pads 105a-n.

With reference to FIG. 2, one embodiment of an electronic device 200 is illustrated showing a partial cross-section view of its key board (dimensions are not to scale). The electronic device 200 can include, but is not limited to, calculators, personal organizers, personal digital assistants, wired and wireless communication devices including cellular telephones, portable computing machines, and so on.

The key board of the electronic device 200 includes a key tree of one or more transparent key pads 205a-n flexibly coupled to a printed circuit board (PCB) 210. The printed circuit board 210 controls input responses associated to the transparent key pads 205a-n being touched by a user. The PCB 210 may be mounted to an electronic device base 215 (e.g. the case of the device 200, a support structure within the device 200, or other component). A key label sheet 230 that includes symbols is disposed under and is visible through the transparent key pads 205a-n to identify the key pads 205a-n as previously described in FIG. 1.

In one embodiment, the PCB 210 has sensors to detect which transparent key pad 205a-n is being pressed. In another embodiment, the PCB has a circuit under each transparent key pad 205a-n that is altered by a pressing the one of transparent key pads 205a-n. The altered circuit provides an indication to the electronic device 200 as to which transparent key pad 205a-n was pressed.

In one embodiment, the electronic device 200 includes a layer 220 formed with collapsible domes 225 located above the PCB 210. Each collapsible dome 225 is aligned with one of the key pads 205a-n. When a collapsible dome 225 is collapsed by pressing one of the transparent key pads 205a-n, the collapsible dome 225 comes into contact with the PCB 210 and alters an electrical circuit within the PCB 210. The location of the altered circuit allows the electronic device 200 to determine which transparent key pad 205a-n has been pressed.

In one embodiment, each collapsible dome 225 includes an electrically conductive material in the domed portion that can alter a circuit on the PCB 210 upon contact. Thus the layer 220 is an electrically conductive layer. In another embodiment, an electrically conductive layer without domes can be disposed between the printed circuit board 210 and the key label sheet 230. Layer 220 may be made with metal, Mylar, polyester, plastic, or any other suitable material, and/or combinations of materials.

In another embodiment, the electronic device 200 includes a cover or top case 235 operable to secure the plurality of transparent key pads 205a-n between the top case 235 and the printed circuit board 210. The top case 235 is configured with openings to allow the transparent key pads 205a-n to extend through the openings or otherwise be accessible.

As discussed above for the keyboard 100, the electronic device 200 is configured to allow the key label sheet 230 to be replaceable with a different key label sheet 230 including symbols that label the plurality of transparent keys pads 205a-n in a different language. In another embodiment, the transparent key pads 205a-n are formed as or with lenses to magnify the symbols visible through the lenses.

In some embodiments, the electrically conductive layer 220 with collapsible domes 225 may be formed with the symbols that identify the key pads 205a-n. Thus, layer 220 can also serve as the key label sheet 230, and the two layers 220 and 230 can be combined into one layer.

One another embodiment, another transparent sheet can be disposed between the top case 235 and the key label sheet 230. The transparent sheet may be rubber to provide a good tactile feel to a user of the electronic device 200 when pressing a transparent key pad 205a-n.

It will be appreciated that in one or more embodiments the layer of key labels 115, 230 can be a Mylar sheet, a paper sheet, a plastic sheet, or other material that can contain symbols. In another embodiment, the keyboard 100 and/or device 200 can be a rotating click keyboard, a user configurable keyboard, or other type of keyboard.

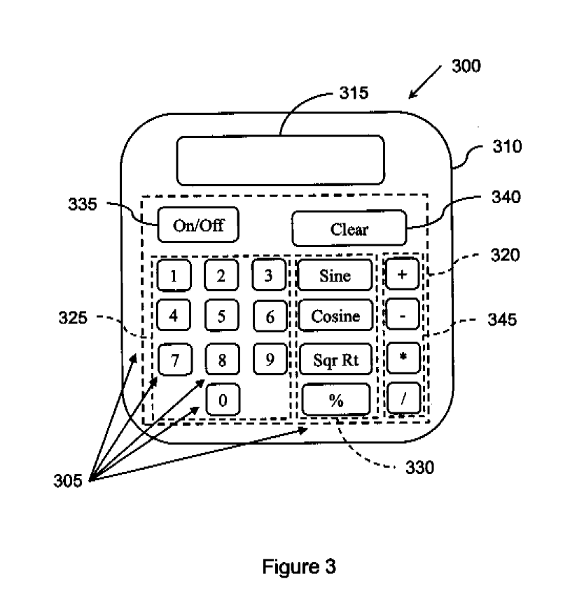

With reference to FIG. 3, one embodiment of a calculator 300 is illustrated with example transparent key pads 305 and labels visible therethrough. For example, the calculator 300 includes a calculator body or case 310 with a display area 315 to display messages/data, A label sheet 320 is located under the transparent key pads 305 to provide symbol labeling as discussed above. Of course, any number of transparent keys pads 305 may be included in a device or keyboard and other types of labels can be used.

The transparent key pads 305 may be grouped into different groups depending on the function of the transparent key pads 305. For example, a number group 325 may include transparent key pads 305 used to enter numerical digits. The symbol printed on the label sheet 320 for each corresponding transparent key pad 305 will be a representation of that numeral.

In another example, a function group 330 may include transparent keys pads 305 that implement mathematical operations. For example, the label sheet 320 may have labels “Sine” and “Cosine” to identify the corresponding trigonometric functions. A “Sqr Rt” label may represent a transparent key pad 305 that will cause the calculator to take the square root of a number when that key is pressed. Other types of labels can include, without limitation, on/off 335, clear 440, math labels 345, and so on.

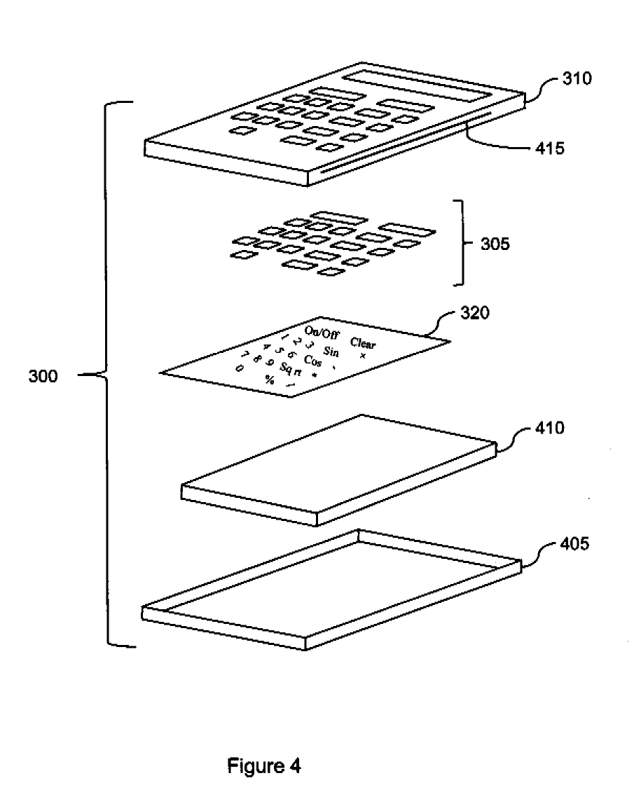

FIG. 4 illustrates an example exploded view of one embodiment of the calculator 300 from FIG. 3. The calculator 300 can be formed with multiple layers, for example, the calculator body 310, the transparent key pads/buttons 305, the label sheet 320, a calculator base 405 and a printed circuit board (PCB) 410. It will be appreciated that the calculator 300 can represent any electronic device that includes a keyboard, for example, personal organizers, personal digital assistants, wired and wireless communication devices including cellular telephones, and portable computing machines, and others.

The keyboard is enclosed in a housing formed by body 310 and base 405. In one embodiment, the housing can include a slot 415 for removing and inserting the label sheet 320.

Example methods may be better appreciated with reference to flow diagrams. While for purposes of simplicity of explanation, the illustrated methodologies are shown and described as a series of blocks, it is to be appreciated that the methodologies are not limited by the order of the blocks, as some blocks can occur in different orders and/or concurrently with other blocks from that shown and described. Moreover, less than all the illustrated blocks may be required to implement an example methodology. Blocks may be combined or separated into multiple components. Furthermore, additional and/or alternative methodologies can employ additional, not illustrated blocks.

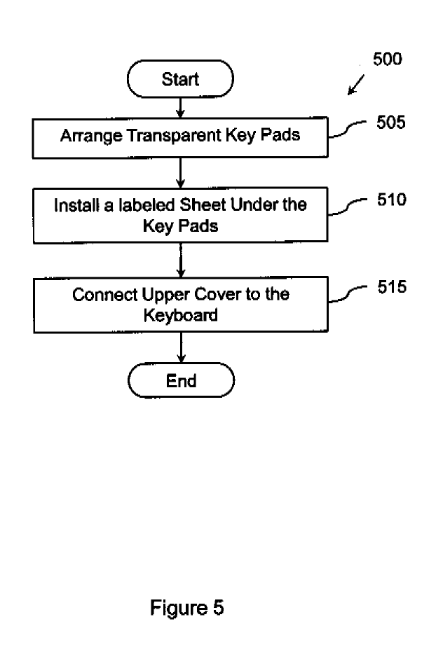

FIG. 5 illustrates one embodiment of a method 500 associated with manufacturing or assembling a keyboard. At block 505, the method begins by arranging a plurality of transparent key pads in a configuration to allow the key pads to be secured between a bottom cover and an upper cover. A label sheet with symbols labeling the functionality represented by one or more of the transparent key pads is installed under the key pads, at block 510, such that the symbols are visible through an aligned key pad. Next, at block 515, the upper cover is secured to the bottom cover so that the key pads are disposed between the upper cover and the bottom cover.

While example systems, methods, and so on have been illustrated by describing examples, and while the examples have been described in considerable detail, it is not the intention of the applicants to restrict or in any way limit the scope of the appended claims to such detail. The illustrative discussions above are not intended to be exhaustive or to limit the invention to the precise forms disclosed. Many modifications and variations are possible in view of the above teachings. The embodiments were chosen and described in order to best explain the principles of the invention and its practical application, to thereby enable others skilled in the art to best utilize the invention and various embodiments with various modifications as are suited to the particular use contemplated.

What is claimed is:

1. A keyboard, comprising:
a printed circuit board to control input responses associated to key pads being touched;
a plurality of transparent key pads flexibly coupled to the printed circuit board; and
a layer of key labels disposed between the printed circuit board and the plurality of transparent key pads, the layer of key labels includes symbols visible through the plurality of transparent key pads to identify an input response associated with a corresponding transparent key pad when a key pad is touched;
where the layer of key labels are removable to be replaced with a different layer of key labels.

2. The keyboard of claim 1, where keyboard is operable to be partially opened to allow the layer of key labels to be slid out of the keyboard and a different layer of key labels to be slid into the keyboard without the key pads or other keyboard components being removed.

3. The keyboard of claim 1, where the transparent key pads are shaped as lenses for visually enhancing the symbols on the printed sheet.

4. The keyboard of claim 1, where the keyboard is enclosed in a housing, the housing including a slot for removing and inserting the layer of key labels.

5. The keyboard of claim 1, further including an electrically conductive layer between the printed circuit board and the layer of key labels.

6. The keyboard of claim 1, where the keyboard includes a bottom cover and an upper cover configured to enclose the printed circuit board, the layer of key labels and the plurality of transparent key pads, where the upper cover is configured with openings to allow a portion of each of the plurality of transparent key pads to movably extend through a corresponding opening.

7. The keyboard of claim 6, where the bottom cover and the upper cover are fastened together with screws.

8. The keyboard of claim 6, where the bottom cover and the upper cover are configured to be interlocked together by snapping the upper cover to the bottom cover.

9. The keyboard of claim 1, where the layer of key labels is a Mylar sheet, a paper sheet, or a plastic sheet.

10. The keyboard of claim 1, where the plurality of transparent key pads are Mylar key pads.

11. The keyboard of claim 1, where the keyboard is a rotating click keyboard or a user configurable keyboard.

12. An electronic device, comprising;
a printed circuit board to control input responses associated to key pads being touched;
a key tree including a plurality of transparent key pads flexibly coupled to the printed circuit board;
a case operable to secure the plurality of transparent key pads between the case and the printed circuit board; and
a key label sheet disposed under the key tree, where the key label sheet includes symbols that label the plurality of transparent key pads, where a symbol is visible through an associated transparent key pad, the key label sheet being replaceable to change the symbols associated with the plurality of transparent key pads.

13. The electronic device of claim 12, where the case includes a slot to allow the key label sheet to be removed and replaceable with a different key label sheet including symbols that label the plurality of transparent keys pads in a different language.

14. The electronic device of claim 12, where the transparent key pads are formed with lenses to magnify the symbols visible through the lenses.

15. The electronic device of claim 12, further comprising an electrically conductive layer between the printed circuit board and the key label sheet where the electrically conductive layer is configured to create an electrical connection on the printed circuit board in response to an individual key pad being pressed.

16. The electronic device of claim 12, where the electronic device is a calculator, a cellular telephone, or a personal digital assistant.

17. A method of labeling a keyboard, the method comprising:
arranging a plurality of transparent key pads in a configuration to allow the transparent key pads to be secured between a bottom cover and an upper cover;
installing a label sheet under the key pads, where the label sheet has symbols labeling the functionality represented by one or more of the transparent key pads; and
connecting the upper cover to the bottom cover so that the key pads are secured between the upper cover and the bottom cover.

18. The method of claim 17, further including:
sliding the label sheet out of the keyboard; and
sliding a different label sheet into the keyboard.

19. The method of claim 18, further including:
partially opening the upper cover prior to sliding the label sheet out of the keyboard.

20. The method of claim 17, further including:
fastening the upper cover to the base with screws subsequent to the installing the label sheet under the key pads.
